(19) United States
(12) Patent Application Publication
(10) Pub. No.: US 2025/0028208 A1
(43) Pub. Date: Jan. 23, 2025

(54) DISPLAY DEVICE

(71) Applicant: Samsung Display Co., LTD., Yongin-si (KR)

(72) Inventors: Hyo Jung KIM, Yongin-si (KR); Ki Yong PARK, Yongin-si (KR); Hye Sun SUNG, Yongin-si (KR); Seung Bo SHIM, Yongin-si (KR)

(73) Assignee: Samsung Display Co., LTD., Yongin-si (KR)

(21) Appl. No.: 18/625,770

(22) Filed: Apr. 3, 2024

(30) Foreign Application Priority Data
Jul. 20, 2023 (KR) 10-2023-0094809

(51) Int. Cl. G02F 1/1345; G02F 1/1333; H10K 59/82

(52) U.S. Cl. CPC G02F 1/13452; G02F 1/133331; H10K 59/82; G02F 2202/22

(57) ABSTRACT

A display device includes a display panel including a first surface and a second surface, the display panel including a base layer and a display layer on the base layer; a driving circuit part disposed on the second surface of the display panel, the driving circuit part including a ground line and a driving circuit; a conductive resin part disposed on the second surface of the display panel, the conductive resin part being electrically connected to the ground line, the conductive resin part including a conductive particle and a resin; and a set bracket covering at least a portion of the second surface of the display panel, the set bracket forming an electrical contact surface with the conductive resin part.

### CROSS-REFERENCE TO RELATED APPLICATION(S)

This application claims priority to and benefits of Korean Patent Application No. 10-2023-0094809 under 35 U.S.C. § 119, filed on Jul. 20, 2023, in the Korean Intellectual Property Office, the entire contents of which are incorporated herein by reference.

### BACKGROUND

### 1. Technical Field

The disclosure relates to a display device.

### 2. Description of the Related Art

Recently, as interest in information displays is increased, research and development of display devices have been continuously conducted.

A display device may include multiple conductive structures. Therefore, in case that an Electro-Static Discharge (ESD) phenomenon occurs adjacent to a conductive structure, the conductive structure may be damaged, and the reliability of an electrical signal may be reduced.

ESD may be eliminated through a predetermined ground path. Accordingly, a plan for thoroughly designing a ground path has been researched.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device in which a ground path having improved ground performance is defined, so that a risk due to ESD can be reduced.

Embodiments also provide a display device in which structural stability can be ensured.

In accordance with an aspect of the disclosure, there is provided a display device that may include a display panel including a first surface, a second surface, a base layer, and a display layer disposed on the base layer, a driving circuit part disposed on the second surface of the display panel and including a ground line, and a driving circuit, a conductive resin part disposed on the second surface of the display panel and being electrically connected to the ground line, the conductive resin part including a conductive particle, and a resin, and a set bracket covering at least a portion of the second surface of the display panel and forming an electrical contact surface with the conductive resin part.

The conductive particle may include at least one of aluminum (AI), gold (Au), copper (Cu), graphene, and zinc (Zn). The resin may include an acrylic-based material.

The conductive resin part may be at least one of a thermally cured conductive resin part and a photo-cured conductive resin part.

The display device may further include a lower layer disposed on the second surface of the display panel and electrically connected to the conductive resin part, wherein the lower layer includes a material having electrical conductivity.

The lower layer, the ground line, the conductive resin part, and the set bracket may form a ground path that removes at least a portion of electro-static discharge (ESD).

The display device may further include a folding area in which at least a portion of the display panel is bent, and a non-folding area in which the display panel is not bent, wherein at least a portion of the conductive resin part is disposed in the folding area.

The conductive resin part in the folding area may couple the display panel and the set bracket to each other.

The display device may further include a cover layer disposed on the display panel and including a cover glass, wherein the conductive resin part in the folding area couples the cover layer and the set bracket to each other.

In a plan view, at least a portion of the conductive resin part may extend in a first direction, and in a plan view at least another portion of the conductive resin part may extend in a second direction different from the first direction.

The driving circuit part may include a cover part disposed adjacent to a side of the display panel, the cover part including the ground line.

The display device may further include a lower layer disposed on the second surface of the display panel and including a material having electrical conductivity. The lower layer may form a heat dissipation structure. In a plan view, at least a portion of the lower layer may extend in a first direction, and in a plan view, at least another portion of the lower layer may extend in a second direction different from the first direction.

The lower layer may include a first lower layer and a second lower layer, which are spaced apart from each other with a filling layer interposed therebetween. The conductive resin part may be directly adjacent to the first lower layer and the second lower layer.

The display device may further include a battery part that stores power. The battery part may be spaced apart from the conductive resin part with a partition wall connected to the set bracket, which is interposed therebetween.

The display panel may include at least one of an organic light emitting diode, an inorganic light emitting element, and a liquid crystal display.

In accordance with another aspect of the disclosure, there is provided a display device that may include a ground path for removing at least a portion of electro-static discharge (ESD). The display device may include a display panel including a pixel circuit, and a light emitting element electrically connected to the pixel circuit, a driving circuit part electrically connected to the pixel circuit and including a ground line, a set bracket overlapping at least a portion of the display device in a plan view, and a conductive resin part having at least a portion disposed between the set bracket and the driving circuit part, wherein the ground path includes an electrical path through which current flows along the ground line, the conductive resin part, and the set bracket.

### BRIEF DESCRIPTION OF THE DRAWINGS

FIG. 1 is a schematic plan view illustrating a display device in accordance with an embodiment of the disclosure.

FIG. 2 is a schematic sectional view illustrating a display device in accordance with an embodiment of the disclosure.

FIG. 3 is a schematic plan view illustrating a display device in accordance with an embodiment of the disclosure.

FIG. 4 is a schematic block diagram illustrating a ground path in accordance with an embodiment of the disclosure.

FIG. 5 is a schematic view illustrating a conductive resin part in accordance with an embodiment of the disclosure.

FIGS. 6 to 9 are schematic sectional views illustrating a display device in accordance with an embodiment of the disclosure.

FIG. 10 is a view schematically illustrating a position relation of the conductive resin part in an area adjacent to a folding area in accordance with an embodiment of the disclosure.

### DETAILED DESCRIPTION OF THE EMBODIMENTS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “comprise,” “comprising,” “has,” “have,” “having,” “include,” and “including”, when used in this specification, specify the presence of stated features, integers, steps, operations, elements, and/or components, but do not preclude the presence and/or addition of one or more other features, integers, steps, operations, elements, components, and/or groups thereof.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Further, an expression that an element such as a layer, region, substrate or plate is placed “on” or “above” another element indicates not only a case where the element is placed “directly on” or “just above” the other element but also a case where a further element is interposed between the element and the other element. An expression that an element such as a layer, region, substrate or plate is placed “beneath” or “below” another element indicates not only a case where the element is placed “directly beneath” or “just below” the other element but also a case where a further element is interposed between the element and the other element.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

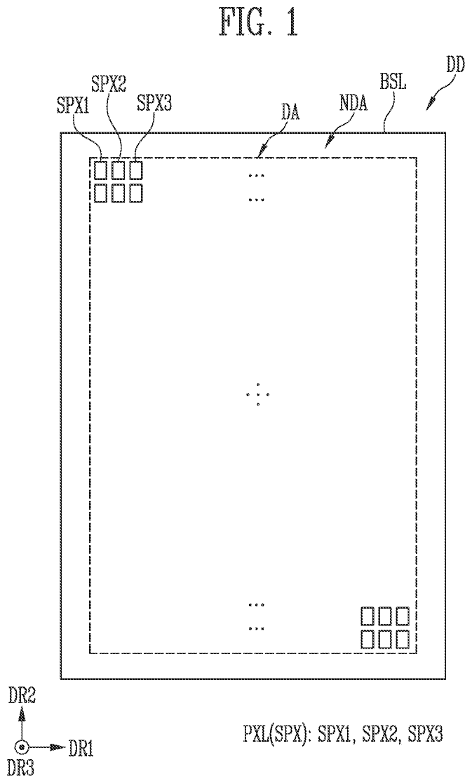

FIG. 1 is a schematic plan view illustrating a display device in accordance with an embodiment of the disclosure.

Referring to FIG. 1, the display device DD may include a base layer BSL and pixels PXL arranged on the base layer BSL. Although not shown in the drawing, the display device DD may further include a driving circuit part (e.g., a scan driver and a data driver) for driving the pixels PXL, lines, and pads.

The display device DD (or the base layer BSL) may include a display area DA and a non-display area NDA. The non-display area NDA may mean an area except the display area DA. The non-display area NDA may surround at least a portion of the display area DA.

The base layer BSL may form a base surface of the display device DD. The base layer BSL may be a rigid substrate including glass, and/or a flexible substrate (or thin film) including a plastic or metal material, and at least one insulating layer. However, the disclosure is not limited to a specific example.

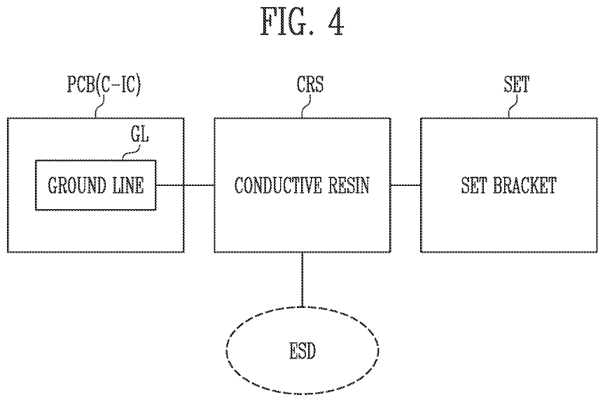

In some embodiments, the base layer BSL may include a layer made of a flexible material (e.g., a structure in which a polyimide layer and a barrier layer are alternately disposed), and at least a portion of the base layer BSL may be bent. The bent portion of the base layer BSL may be disposed under a portion of another base layer BSL, and form an area in which a driving circuit part PCB (see FIG. 4) and the like are disposed. Accordingly, the area of the non-display area NDA (e.g., a dead space) can be decreased.

The display area DA may mean an area in which the pixels PXL are disposed. The non-display area NDA may mean an area in which the pixels PXL are not disposed. The lines, and the pads, which are connected to the pixels PXL of the display area DA, may be disposed in the non-display area NDA.

In accordance with an embodiment, the pixels PXL (or sub-pixels SPX) may be arranged according to a stripe arrangement structure, a PENTILE™ arrangement structure, or the like. However, the disclosure is not limited thereto, and various embodiments may be applied in the disclosure.

In accordance with an embodiment, the pixel PXL (or the sub-pixels SPX) may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel. At least one first sub-pixel SPXL1, at least one second sub-pixel SPXL2, and at least one third sub-pixel SPXL3 may constitute a pixel unit configured to emit lights of various colors.

For example, each of the first sub-pixel SPXL1, the second sub-pixel SPXL2, and the third sub-pixel SPXL3 may emit light of one color. For example, the first sub-pixel SPXL1 may be a red pixel emitting light of red (e.g., a first color), the second sub-pixel SPXL2 may be a green pixel emitting light of green (e.g., a second color), and the third sub-pixel SPXL3 may be a blue pixel emitting light of blue (e.g., a third color). In accordance with an embodiment, a number of second sub-pixels SPXL2 may be greater than a number of first sub-pixels SPXL1 and a number of third sub-pixels SPXL3. However, the color, kind, and/or number of first, second, and third sub-pixels SPXL1, SPXL2, and SPXL3 constituting each pixel unit are not limited to a specific example.

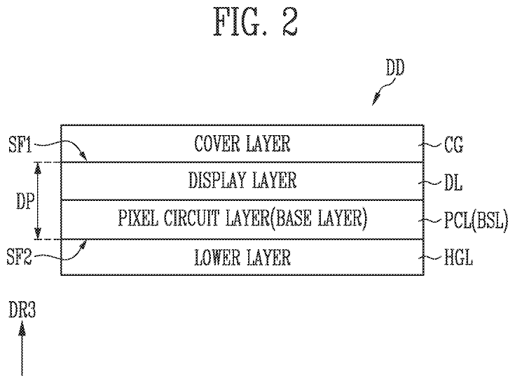

FIG. 2 is a schematic sectional view illustrating a display device in accordance with an embodiment of the disclosure.

Referring to FIG. 2, the display device DD may include a display panel DP, a cover layer CG, and a lower layer HGL.

The display panel DP may include a pixel-circuit layer PCL (e.g., a backplane layer) including a base layer BSL and a display layer DL disposed on the pixel-circuit layer PCL.

The display panel DP may include a first surface SF1 and a second surface SF2. The first surface SF1 may be a front surface, and the second surface SF2 may be a rear surface. The first surface SF1 may be adjacent to the pixel-circuit layer PCL. The first surface SF1 may be adjacent to the display layer DL. The second surface SF2 may be adjacent to the pixel-circuit layer PCL.

The pixel-circuit layer PCL may be a layer including a pixel circuit for driving a pixel PXL formed by the display layer DL (or a light emitting element included in the display layer DL). The pixel-circuit layer PCL may include the base layer BSL, conductive layers for forming pixel circuits, and insulating layers disposed on the conductive layers.

The display layer DL may be disposed on the pixel-circuit layer PCL. In some embodiments, the display layer DL may include a light emitting element. In some embodiments, the light emitting element may include an Organic Light Emitting Diode (OLED). In other embodiments, the light emitting element may include an inorganic light emitting element including an inorganic material. In other embodiments, the display layer DL may include a Liquid Crystal Display (LCD). However, the disclosure is not limited thereto.

In some embodiments, the display layer DL may further include a polarizing layer POL disposed adjacent to the cover layer CG. The polarizing layer POL may allow light provided from the display layer DL to be transmitted therethrough, and reflect light introduced from the outside. In some embodiments, the polarizing layer POL may include a polarizer which polarizes light applied along a polarization axis.

The cover layer CG may be disposed on the first surface SF1 of the display panel DP. The cover layer CG may be roughly disposed at an outer portion with respect to a display direction (e.g., a third direction DR3). In some embodiments, the cover layer CG may include a cover glass.

In some embodiments, the cover layer CG may cover the front surface of the display panel DP. In some embodiments, the cover layer CG may protect the display panel DP, and include a glass material (e.g., ultra-thin glass). However, the disclosure is not limited thereto.

The lower layer HGL may be disposed on the second surface SF2 of the display panel DP. The lower layer HGL may cover the rear surface of the display panel DP.

In some embodiments, the lower layer HGL may include a heat dissipation layer, and form a heat dissipation structure. For example, the lower layer HGL may include a material having a relatively high thermal electrical conductivity. In some embodiments, the lower layer HGL may form a portion of a ground path. For example, the lower layer HGL may include a material having electrical conductivity. In some embodiments, the lower layer HGL may include copper (Cu). However, the disclosure is not limited thereto.

A structure of a display device DD including a conductive resin part CRS as a structure in which a ground path for reducing an Electro-Static Discharge (ESD) risk is formed will be described. For convenience of description, descriptions of portions overlapping with those described above will be simplified or will not be repeated.

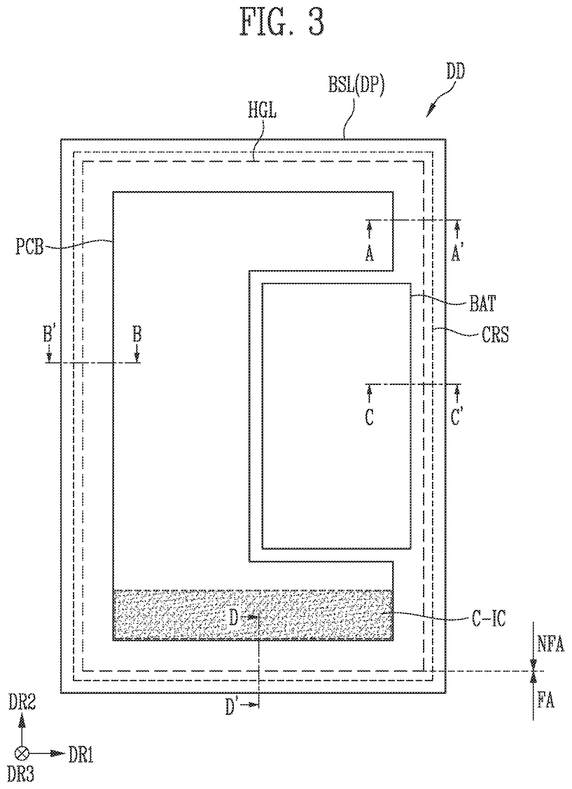

FIG. 3 is a schematic plan view illustrating a display device in accordance with an embodiment of the disclosure. FIG. 3 schematically illustrates a planar structure in which the display device is observed from the bottom. For example, FIG. 3 may schematically illustrate components disposed under the display panel DP (e.g., the base layer BSL).

FIG. 4 is a schematic block diagram illustrating a ground path in accordance with an embodiment of the disclosure. For example, FIG. 4 schematically illustrates a connection relationship between conductive components forming the ground path in accordance with an embodiment of the disclosure.

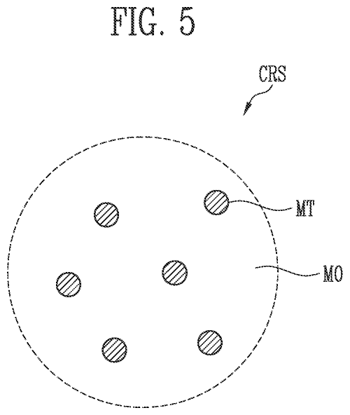

FIG. 5 is a schematic view illustrating a conductive resin part CRS in accordance with an embodiment of the disclosure. FIG. 5 schematically illustrates materials forming the conductive resin part CRS in accordance with an embodiment of the disclosure.

Referring to FIGS. 3 to 5, the display device DD may further include a driving circuit part PCB, a battery part BAT, and a conductive resin part CRS, which are disposed on a rear surface of the base layer BSL (e.g., the second surface SF2 of the display panel DP).

In some embodiments, the lower layer HGL may be entirely disposed on the rear surface of the base layer BSL. For example, the lower layer HGL may extend onto a plane defined by a first direction DR1 and a second direction DR2. In some embodiments, the lower layer HGL may overlap the driving circuit part PCB, the battery part BAT, and the conductive resin part CRS in a plan view. In some embodiments, the lower layer HGL may cover a wide area of the display panel DP in a plan view as compared with the driving circuit part PCB.

In some embodiments, the driving circuit part PCB may be disposed to overlap the conductive resin part CRS and the lower layer HGL on the rear surface of the base layer BSL. In some embodiments, the driving circuit part PCB may not overlap the battery part BAT in a plan view.

In some embodiments, the driving circuit part PCB may include a circuit board and a driving chip. The circuit board and the driving chip may be electrically connected to each other. The circuit board may include a driving circuit. The driving chip may include a scan driver capable of supplying a scan signal for driving the pixels PXL and a data driver capable of supplying a data signal for driving the pixels PXL. In some embodiments, the circuit board may be a flexible circuit board. In some embodiments, the driving circuit part PCB may be electrically connected to a pixel circuit.

In some embodiments, the driving circuit part PCB may include a cover part C-IC. The cover part C-IC may be disposed adjacent to a side of the display panel DP. For example, the cover part C-IC may be a portion of the driving circuit part PCB, and may be disposed at a side adjacent to a folding area FA of the display panel DP. The folding area FA may mean an area in which a portion of the display panel DP is bent. The folding area FA may be adjacent to a side of a non-folding area NFA as an area in which the display panel DP is not bent. In some embodiments, the cover part C-IC may include a structure in which a conductive structure is patterned on a film.

In some embodiments, the driving circuit part PCB (e.g., the cover part C-IC) may include a ground line GL. For example, the ground line GL may form a ground power source as at least a portion of the conductive structure formed in the cover part C-IC.

The battery part BAT may be disposed on the rear surface of the base layer BSL. In some embodiments, the battery part BAT may be disposed not to overlap the driving circuit part PCB in a plan view. In some embodiments, the battery part BAT may store and supply power required when the display device DD operates.

In some embodiments, the battery part BAT may not overlap the conductive resin part CRS in a plan view. For example, the conductive resin part CRS may be selectively disposed in a partial area on the rear surface of the base layer BSL not to be directly adjacent to the battery part BAT. Thus, exchange, repair, and the like of the battery part BAT can be readily performed.

The conductive resin part CRS may be entirely disposed on the rear surface of the base layer BSL. For example, the conductive resin part CRS may extend onto a plane defined by the first direction DR1 and the second direction DR2. The conductive resin part CRS may overlap the driving circuit part PCB (e.g., the cover part C-IC) and the lower layer HGL in a plan view.

Referring to FIG. 4, the conductive resin part CRS may form a portion of a ground path for removing at least a portion of ESD. The display device DD in accordance with the embodiment of the disclosure may include a ground path capable of removing at least a portion of ESD.

ESD formed at the inside or the outside of the display device DD may be discharged to the outside along the ground path of the display device DD, and accordingly, a risk due to the ESD in the display device DD can be reduced.

The ground path may include the ground line GL, the conductive resin part CRS, and a set bracket SET.

In some embodiments, the conductive resin part CRS may have a conductive property. For example, referring to FIG. 5, the conductive resin part CRS may include a conductive particle MT and a resin MO.

The conductive particle MT may be a conductive material. For example, the conductive particle MT may include a metal. The conductive particle MT may include one or more metal material(s) having low resistance. For example, the conductive particle MT may include at least one selected from the group consisting of aluminum (Al), gold (Au), copper (Cu), graphene, and zinc (Zn). However, the disclosure is not limited thereto.

The resin MO may include various materials. For example, the resin MO may include an acrylic-based material. However, the disclosure is not limited thereto.

In some embodiments, the conductive resin part CRS may be a member cured as a base resin including the conductive particle MT thermally cured or photo-cured (e.g., ultraviolet (UV)-cured). For example, the base resin may include a material (e.g., an acrylic-based monomer) for forming the resin MO. The base resin may further include a photoinitiator or a thermoinitiator. Accordingly, the resin MO provided through curing may further include a photoinitiator or a thermoinitiator. However, the disclosure is not limited thereto.

In some embodiments, the conductive resin part CRS may be electrically connected to the ground line GL. For example, the conductive resin part CRS may form an electrical contact surface with the ground line GL. In some embodiments, the conductive resin part CRS and at least a portion of the ground line GL may be in contact with each other.

In some embodiments, the conductive resin part CRS may be electrically connected to the set bracket SET. For example, the conductive resin part CRS may form an electrical contact surface with the set bracket SET. In some embodiments, the conductive resin part CRS and at least a portion of the set bracket SET may be in contact with each other.

Accordingly, ESD may be discharged to the outside through the ground path.

In accordance with an embodiment, the conductive resin part CRS distributed in a relative wide area under the display panel DP may form a ground path. The conductive resin part CRS may relatively widely define a contact surface with other components.

Experimentally, in case that a component forming a ground path covers a narrow area, it may be difficult to ensure the reliability of ground performance. For example, in case that a conductive pin or the like is used to form a ground path, an oxide layer may be formed in an area between the conductive pin and another component electrically in contact therewith, and therefore, it may be difficult for the ground path to be normally defined.

However, in accordance with an embodiment of the disclosure, the conductive resin part CRS covering a relatively wide area instead of the conductive pin defined in a narrow area can form a ground path, and accordingly, the ground path having high reliability can be formed.

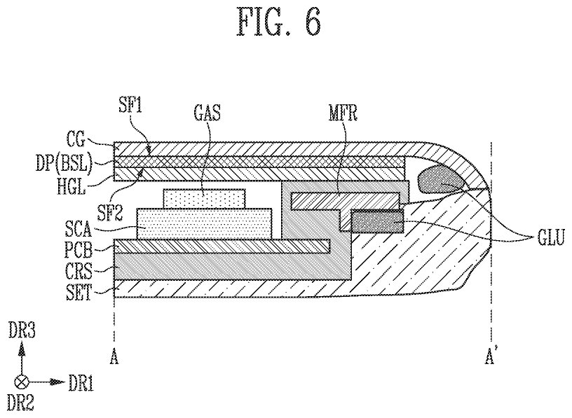

A sectional structure of a display device DD including the conductive resin part CRS will be described in conjunction with FIGS. 6 to 10.

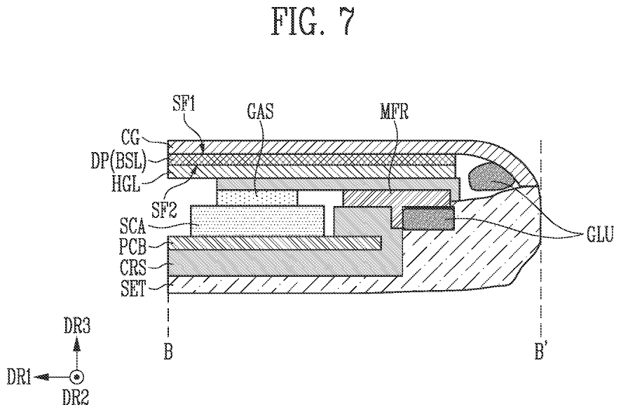

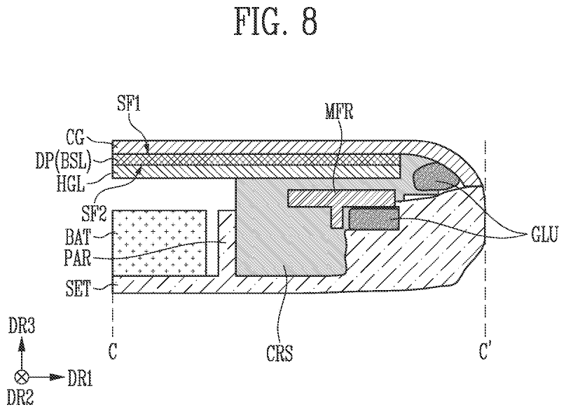

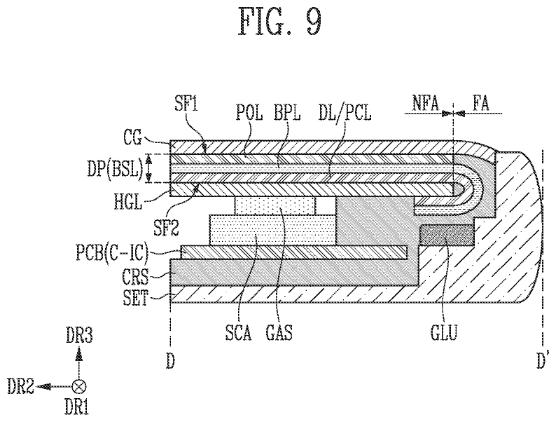

FIGS. 6 to 9 are schematic sectional views illustrating a display device in accordance with an embodiment of the disclosure. For example, FIG. 6 is a schematic cut-away sectional view taken along line A-A′ shown in FIG. 3. FIG. 7 is a schematic cut-away sectional view taken along line B-B′shown in FIG. 3. FIG. 8 is a schematic cut-away sectional view taken along line C-C′ shown in FIG. 3. FIG. 9 is a schematic cut-away sectional view taken along line D-D′ shown in FIG. 3.

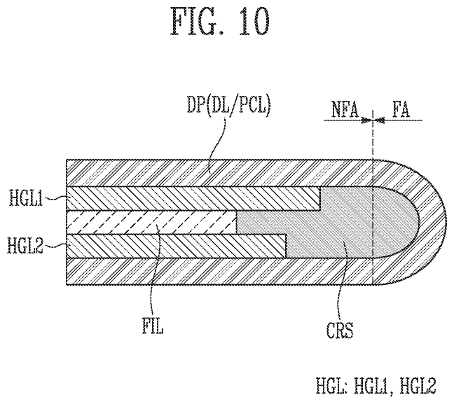

FIG. 10 is a view schematically illustrating a position relation of the conductive resin part in an area adjacent to a folding area in accordance with an embodiment of the disclosure. FIG. 10 may schematically illustrate a structure in which the conductive resin part CRS is disposed in a space defined by the folded display panel DP.

The display device DD in accordance with an embodiment of the disclosure may further include a shield can SCA, a gasket GAS, a middle frame MFR, and a gluing part GLU.

Referring to FIGS. 6 to 10, the shield can SCA, the gasket GAS, and the middle frame MFR may be disposed under the display panel DP (e.g., the base layer BSL), and be disposed between the lower layer HGL and the set bracket SET.

The shield can SCA may be disposed on the driving circuit part PCB. The shield can SCA may be disposed under the display panel DP (e.g., the base layer BSL), and be disposed between the gasket GAS and the driving circuit part PCB. The shield can SCA may protect other members from electromagnetic wave interference. The shield can SCA may include a metal material. However, the disclosure is not limited thereto.

The gasket GAS may be disposed on the driving circuit part PCB. The gasket GAS may be disposed between the lower layer HGL and the shield can SCA. The gasket GAS may protect a component of the display device DD from external influence (dust, electromagnetic waves, or the like).

The middle frame MFR may be disposed under the lower layer HGL (e.g., the base layer BSL, and be disposed between the set bracket SET and the display panel DP. The middle frame MFR may include a material having a relatively high rigidity. In some embodiments, at least a portion of the middle frame MFR may be covered by the conductive resin part CRS, and be coupled to the set bracket SET by the gluing part GLU including various gluing materials.

The set bracket SET may form a lower member of the display device DD. The set bracket SET may form a housing of the display device DD. The set bracket SET may be disposed under the display panel DP.

The set bracket SET may cover the conductive resin part CRS. For example, the set bracket SET may form a contact surface with the conductive resin part CRS, and be electrically connected to the conductive resin part CRS. The set bracket SET may be coupled to the cover layer CG. The set bracket SET may be coupled to the middle frame MFR by the gluing part GLU.

As described above, the set bracket SET may form a ground path.

The set bracket SET may include a rigid material, and have electrical conductivity. The conductive material included in the set bracket SET is not particularly limited. The set bracket SET may fix the display panel DP. The set bracket SET may stably maintain components of the display device DD.

In some embodiments, the display device DD may include a folding area FA in which a portion of the display panel DP is bent and a non-folding area NFA in which the display panel DP is not bent.

In some embodiments, the polarizing layer POL may be disposed in the non-folding area NFA, and may not be disposed in the folding area FA. The lower layer HGL may be disposed in the non-folding area NFA, and may not be disposed in the folding area FA.

In some embodiments, the cover layer CG may be disposed throughout the non-folding area NFA from the folding area FA. In some embodiments, the conductive resin part CRS may be disposed throughout the non-folding area NFA from the folding area FA.

In some embodiments, the conductive resin part CRS may fill at least a portion of a space in the folding area FA. For example, the conductive resin part CRS may be disposed in an inner area formed as the display panel DP is bent, and be disposed in an outer area formed as the display panel DP is bent. Accordingly, the conductive resin part CRS in the folding area FA may couple the display panel DP, the cover layer CG, and the set bracket SET to each other. Thus, the conductive resin part CRS can protect components in the folding area FA, and the stability of the entire display device DD can be ensured.

In accordance with an embodiment (FIG. 10), the lower layer HGL may include a first lower layer HGL1 and a second lower layer HGL2, and the display device DD may further include a filling layer FIL disposed between the first lower layer HGL1 and the second lower layer HGL2. In some embodiments, the first lower layer HGL1 may be adjacent to a portion of the display panel DP formed at a front surface, and the second lower layer HGL2 may be adjacent to a portion of the display panel DP formed at a rear surface. In accordance with an embodiment, the conductive resin part CRS may be directly adjacent to the filling layer FIL, the first lower layer HGL1, and the second lower layer HGL2 in the folding area FA.

In some embodiments, the display device DD may further include a protective layer BPL for protecting the display panel DP in the folding area FA. The protective layer BPL may be disposed throughout the non-folding area NFA from the folding area FA. The protective layer BPL may be formed through the same process as at least one of insulating layers for forming the display panel DP. In some embodiments, the protective layer BPL may be disposed on another portion of the display panel DP, which is disposed under the display panel DP forming the front surface as at least a portion of the protective layer BPL is bent. The protective layer BPL may include an inorganic material. However, the disclosure is not limited to a specific example.

The battery part BAT may be disposed on the set bracket SET. The battery part BAT may be disposed between the lower layer HGL and the set bracket SET.

In some embodiments, the display device DD may include a partition wall PAR. The partition wall PAR may be adjacent to the battery part BAT. In some embodiments, the battery part BAT and the conductive resin part CRS may be separated from each other. In some embodiments, the partition wall PAR may include a rigid material. In some embodiments, the partition wall PAR may be integrally formed with the set bracket SET.

In some embodiments, the partition wall PAR may be adjacent to the battery part BAT. In case that a base resin is supplied downwardly from the display panel DP so as to form the conductive resin part CRS, a risk that the base resin will be directly adjacent to the battery part BAT can be prevented. The base resin may be provided as a cured conductive resin part CRS as a curing process is performed. In case that the cured conductive resin part CRS is directly adjacent to the battery part BAT, the battery part BAT may be coupled to the conductive resin part CRS disposed at a first half under the display panel DP. This may be disadvantageous in repair, replacement, and the like of the battery part BAT. However, the partition wall PAR is formed, so that the above-described risk can be prevented.

The conductive resin part CRS may be disposed under the display panel DP to be adjacent to one or more components.

The conductive resin part CRS may be disposed between the driving circuit part PCB and the set bracket SET. The conductive resin part CRS may be disposed between the middle frame MFR and the lower layer HGL. The conductive resin part CRS may be directly adjacent to the middle frame MFR.

Accordingly, the conductive resin part CRS may fill areas under the display panel DP. The conductive resin part CRS may support components of the display device DD while serving as a ground path for removing ESD.

For example, the conductive resin part CRS may be prepared by injecting the base resin including the resin MO and the conductive particle MT into a portion under the display panel DP and curing the base resin during a manufacturing process of the display device DD.

In case that the base resin is supplied to the portion under the display panel DP, the base resin may fill areas under the display panel DP since the base resin has a relatively flexible property. After that, the base resin may be thermally cured or photo-cured (e.g., ultraviolet (UV)-cured).

A process of supplying the base resin to the portion under the display panel DP and a curing process can be performed without addition of additional process facilities or an excessive change in process procedure when the manufacturing process of the display device DD is performed.

The base resin which does not have an excessively strong rigidity can be used to form the conductive resin part CRS, and thus damage of the display panel DP and components thereunder can be prevented.

As described above, the conductive resin part CRS may be electrically connected to the set bracket SET with a wide area, and be electrically connected to the lower layer HGL with a wide area. For example, the conductive resin part CRS may be electrically connected to another component with a wide area (e.g., the area of an area extending on a plane), as compared with a relatively acute electrical connection member (e.g., a conductive pin).

For example, in edge areas of the display panel DP corresponding to a side at which the cover part C-IC is not disposed (see FIGS. 6 to 8), the conductive resin part CRS may be electrically connected to the ground line GL included in the driving circuit part PCB, and be in contact with the set bracket SET.

For example, in an edge area of the display panel DP corresponding to a side at which the cover part C-IC is disposed (see FIG. 9), the conductive resin part CRS may be electrically connected to the ground line GL included in the driving circuit part PCB, and be in contact with the set bracket SET.

Consequently, in accordance with an embodiment of the disclosure, processes are optimized and ground performance is enhanced. Thus, the reliability of electrical characteristics applied to the entire display device DD can be improved, and the stability of the display device DD can be ensured.

In accordance with the disclosure, there can be provided a display device in which a ground path having improved ground performance is defined, so that a risk due to ESD can be reduced.

In accordance with the disclosure, there can be provided a display device in which structural stability can be ensured.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure.

What is claimed is:

1. A display device, comprising:
a display panel including:
a first surface;
a second surface;
a base layer; and
a display layer disposed on the base layer;
a driving circuit part disposed on the second surface of the display panel and including:
a ground line; and
a driving circuit;
a conductive resin part disposed on the second surface of the display panel and being electrically connected to the ground line, the conductive resin part including:
a conductive particle; and
a resin; and
a set bracket covering at least a portion of the second surface of the display panel and forming an electrical contact surface with the conductive resin part.

2. The display device of claim 1, wherein
the conductive particle includes at least one of aluminum (Al), gold (Au), copper (Cu), graphene, and zinc (Zn), and
the resin includes an acrylic-based material.

3. The display device of claim 1, wherein the conductive resin part is at least one of a thermally cured conductive resin part and a photo-cured conductive resin part.

4. The display device of claim 1, further comprising:
a lower layer disposed on the second surface of the display panel and electrically connected to the conductive resin part,
wherein the lower layer includes a material having electrical conductivity.

5. The display device of claim 4, wherein the lower layer, the ground line, the conductive resin part, and the set bracket form a ground path that removes at least a portion of electro-static discharge (ESD).

6. The display device of claim 1, further comprising:
a folding area in which at least a portion of the display panel is bent; and
a non-folding area in which the display panel is not bent,
wherein at least a portion of the conductive resin part is disposed in the folding area.

7. The display device of claim 6, wherein the conductive resin part in the folding area couples the display panel and the set bracket to each other.

8. The display device of claim 6, further comprising:
a cover layer disposed on the display panel and including a cover glass,
wherein the conductive resin part in the folding area couples the cover layer and the set bracket to each other.

9. The display device of claim 1, wherein
in a plan view, at least a portion of the conductive resin part extends in a first direction, and
in a plan view, at least another portion of the conductive resin part extends in a second direction different from the first direction.

10. The display device of claim 1, wherein the driving circuit part includes a cover part disposed adjacent to a side of the display panel, the cover part including the ground line.

11. The display device of claim 1, further comprising:
a lower layer disposed on the second surface of the display panel and including a material having electrical conductivity, wherein
the lower layer forms a heat dissipation structure,
in a plan view, at least a portion of the lower layer extends in a first direction, and
in a plan view, at least another portion of the lower layer extends in a second direction different from the first direction.

12. The display device of claim 11, wherein
the lower layer includes a first lower layer and a second lower layer, which are spaced apart from each other with a filling layer interposed therebetween, and
the conductive resin part is directly adjacent to the first lower layer and the second lower layer.

13. The display device of claim 1, further comprising:
a battery part that stores power,
wherein the battery part is spaced apart from the conductive resin part with a partition wall connected to the set bracket, which is interposed therebetween.

14. The display device of claim 1, wherein the display panel includes at least one of an organic light emitting diode, an inorganic light emitting element, and a liquid crystal display.

15. A display device including a ground path for removing at least a portion of electro-static discharge (ESD), the display device comprising:
a display panel including:
a pixel circuit; and
a light emitting element electrically connected to the pixel circuit;
a driving circuit part electrically connected to the pixel circuit and including a ground line;
a set bracket overlapping at least a portion of the display device in a plan view; and
a conductive resin part having at least a portion disposed between the set bracket and the driving circuit part,
wherein the ground path includes an electrical path through which current flows along the ground line, the conductive resin part, and the set bracket.
